(19) United States
(12) Patent Application Publication
(10) Pub. No.: US 2022/0293543 A1
(43) Pub. Date: Sep. 15, 2022

(54) ELECTRICALLY CONDUCTIVE PILLAR, BONDING STRUCTURE, ELECTRONIC DEVICE, AND METHOD FOR MANUFACTURING ELECTRICALLY CONDUCTIVE PILLAR

(71) Applicant: DIC Corporation, Tokyo (JP)

(72) Inventors: Ryota YAMAGUCHI, Chiba (JP); Makoto YADA, Tokyo (JP)

(73) Assignee: DIC Corporation, Tokyo (JP)

(21) Appl. No.: 17/770,620

(22) PCT Filed: Sep. 17, 2020
(86) PCT No.: PCT/JP2020/035176

§ 371 Date: Apr. 20, 2022

(30) Foreign Application Priority Data
Oct. 25, 2019 (JP) 2019-194504

(51) Int. Cl. H01L 23/00

(52) U.S. Cl. CPC H01L 24/13; H01L 24/16; H01L 24/17; H01L 24/11; H01L 2224/11505; H01L 2224/17051; H01L 2224/16221; H01L 2224/13005; H01L 2224/13011; H01L 2224/13014; H01L 2224/13018; H01L 2224/13147; H01L 2224/13139; H01L 2224/13647; H01L 2224/13616; H01L 2224/13639; H01L 2224/13611; H01L 2224/13576; H01L 2224/13582; H01L 2224/13553; H01L 2224/13541; H01L 24/73; H01L 24/32; H01L 2224/73204; H01L 2224/32221

(57) ABSTRACT

An electrically conductive pillar that can bond a base member and a member to be bonded together with high bonding strength with a bonding layer interposed therebetween and a method for manufacturing the same. Specifically, an electrically conductive pillar 1 is composed of a sintered body 12 of metal micro-particles disposed on a base member 11. The average particle size of the metal micro-particles is less than 1 μm as measured using a small-angle X-ray scattering method. An upper surface 12b of the sintered body 12 has a concave shape recessed on the base member 11 side. The metal micro-particles are preferably made of one or more metals selected from Ag and Cu.

### TECHNICAL FIELD

The present invention relates to an electrically conductive pillar, a bonding structure, an electronic device, and a method for manufacturing an electrically conductive pillar.

### BACKGROUND ART

Hitherto, a flip-chip packaging method has been used as a method for electrically connecting a semiconductor chip and a semiconductor substrate together. The flip-chip packaging method is a bonding method in which bumps are formed on electrode pads placed on a semiconductor chip, the semiconductor chip and a semiconductor substrate are placed opposite to each other with the bumps interposed therebetween, and the bumps are melted by heating. In the flip-chip packaging method, electrically conductive pillars are formed on electrode pads placed on a semiconductor chip and bumps are formed thereon in some cases.

Copper pillars are electrically conductive pillars formed on electrode pads. Hitherto, a copper pillar has been formed by a method below. A plating base layer and a resist layer are formed on a semiconductor chip having an electrode pad in this order. Next, the resist layer is partly removed, whereby the plating base layer on the electrode pad is exposed. Subsequently, the copper pillar is formed on the plating base layer by an electroplating method. After that, the resist layer is removed and the plating base layer disposed under the resist layer is removed by etching.

A method in which metal particles and solder are used has been reported as a method for forming a copper pillar without using any electroplating method (refer to, for example, Patent Literature 1).

### CITATION LIST

### Patent Literature

PTL 1: U.S. Pat. No. 9,859,241

### SUMMARY OF INVENTION

### Technical Problem

However, when conventional electrically conductive pillars are formed on a semiconductor chip, bumps are formed thereon, and the semiconductor chip and a semiconductor substrate electrically connected together with the bumps interposed therebetween, the bonding strength between the semiconductor chip and the semiconductor substrate is not sufficiently obtained in some cases. Therefore, an electrically conductive pillar that can bond a semiconductor chip and a semiconductor substrate together with high bonding strength with a bonding layer such as a bump interposed therebetween has been required.

The present invention has been made in view of the above circumstances and it is an object of the present invention to provide an electrically conductive pillar which is disposed on a base member and which can bond the base member and a member to be bonded together with high bonding strength with a bonding layer interposed therebetween and to provide a method for manufacturing the same.

It is an object of the present invention to provide a bonding structure which includes an electrically conductive pillar of the present invention and which can bond a base member and a member to be bonded together with high bonding strength and to provide an electronic device.

### Solution to Problem

[1] An electrically conductive pillar is composed of a sintered body of metal micro-particles disposed on a base member.

The average particle size of the metal micro-particles is less than 1 μm as measured using a small-angle X-ray scattering method.

An upper surface of the sintered body has a concave shape recessed on the base member side.

[2] In the electrically conductive pillar specified in [1], the metal micro-particles are made of one or more metals selected from Ag and Cu.

[3] A bonding structure disposed between a base member and a member to be bonded, the member to be bonded being disposed opposite to the base member, includes

an electrically conductive pillar composed of a sintered body of metal micro-particles disposed on the base member, the average particle size of the metal micro-particles being less than 1 μm as measured using a small-angle X-ray scattering method, an upper surface of the sintered body having a concave shape recessed on the base member side, and

a bonding layer provided along the concave shape of the electrically conductive pillar.

[4] In the bonding structure specified in [3], the electrically conductive pillar has a plurality of groove sections that extend from the upper surface toward the base member and has anchoring sections made by the groove sections being filled with portions of the bonding layer.

[5] In the bonding structure specified in [3] or [4], the bonding layer is made of an alloy containing one or more metals selected from Sn, Pb, Ag, and Cu.

[6] The bonding structure specified in any one of [3] to [5] includes an intermetallic compound layer between the electrically conductive pillar and the bonding layer.

[7] An electronic device includes the bonding structure specified in any one of [3] to [6]. [8] In the electronic device specified in [7], a plurality of the bonding structures are included, and part or all of the bonding structures have different shapes.

[9] A method for manufacturing an electrically conductive pillar includes a step of forming a columnar body on a base member using metal micro-particles with an average primary particle size of less than 1 μm, and

a step of forming on an upper surface a sintered body having a concave shape recessed on the base member side by sintering the columnar body.

[10] In the method for manufacturing the electrically conductive pillar specified in [9], the metal micro-particles are made of one or more metals selected from Ag and Cu.

[11] The method for manufacturing the electrically conductive pillar specified in [9] or [10] includes a step of exposing at least a surface of the columnar body to an oxygen-containing atmosphere with an oxygen concentration of 200 ppm or more before the step of forming the sintered body.

### Advantageous Effects of Invention

An electrically conductive pillar of the present invention is composed of a sintered body of metal micro-particles that is disposed on a base member, the average particle size of the metal micro-particles is less than 1 μm as measured using a small-angle X-ray scattering method, and an upper surface of the sintered body has a concave shape recessed on the base member side. Therefore, providing a bonding layer along the concave shape of the electrically conductive pillar allows the bonding layer to be formed such that the bonding layer enters the concave shape of the electrically conductive pillar. In addition, the electrically conductive pillar of the present invention is composed of the sintered body of the metal micro-particles, which have an average particle size of less than 1 μm as measured using the small-angle X-ray scattering method, and has a porous structure made of the metal micro-particles fused by sintering. Therefore, when the bonding layer is formed, molten material to be formed into the bonding layer enters the porous structure of the sintered body and solidifies. These allow the electrically conductive pillar of the present invention to have a large bonding area with the bonding layer and allow the electrically conductive pillar of the present invention to be bonded to the bonding layer with higher bonding strength as compared to, for example, electrically conductive pillars which are formed by an electroplating method, which therefore have a flat upper surface parallel to a base member, and which are made of a dense metal. As a result, in accordance with the electrically conductive pillar of the present invention, the base member and a member to be bonded can be bonded together with high bonding strength with the bonding layer interposed therebetween.

Furthermore, since the electrically conductive pillar of the present invention is composed of the sintered body of the metal micro-particles, which have an average particle size of less than 1 μm as measured using the small-angle X-ray scattering method, and has the porous structure, which is made of the metal micro-particles fused by sintering, stress caused by a difference between thermal expansion coefficients can be reduced as compared to dense bulk metals formed using an electroplating method or the like and excellent durability is obtained.

A bonding structure of the present invention is disposed between a base member and a member to be bonded and includes the electrically conductive pillar of the present invention and a bonding layer provided along the concave shape of the electrically conductive pillar. Thus, the bonding structure of the present invention is such that the bonding layer enters the concave shape of the electrically conductive pillar and the base member and the member to be bonded are bonded together with high bonding strength with the bonding layer interposed therebetween.

An electronic device of the present invention includes the bonding structure of the present invention and is therefore such that the base member and the member to be bonded are bonded together with high bonding strength.

In accordance with a method for manufacturing an electrically conductive pillar of the present invention, the electrically conductive pillar of the present invention can be manufactured without using any electroplating method such that a base member and a member to be bonded can be bonded together with high bonding strength with a bonding layer interposed therebetween.

### BRIEF DESCRIPTION OF DRAWINGS

FIG. 1 is a side view of an example of an electrically conductive pillar of this embodiment.

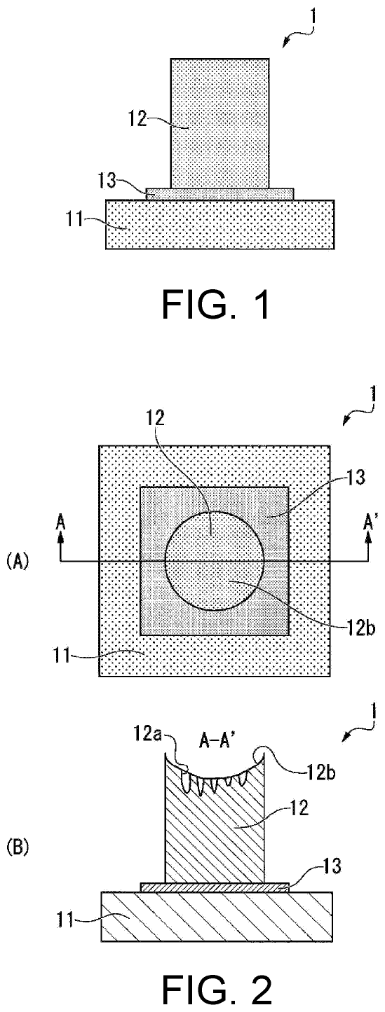

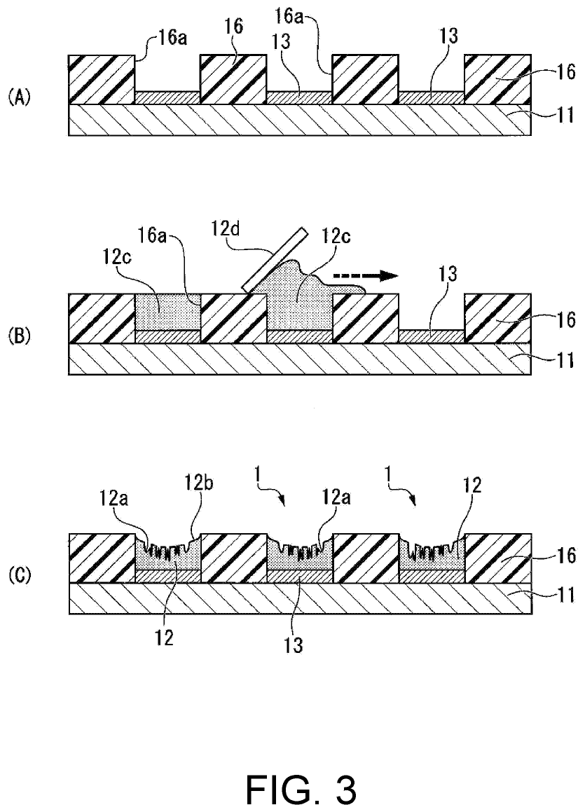

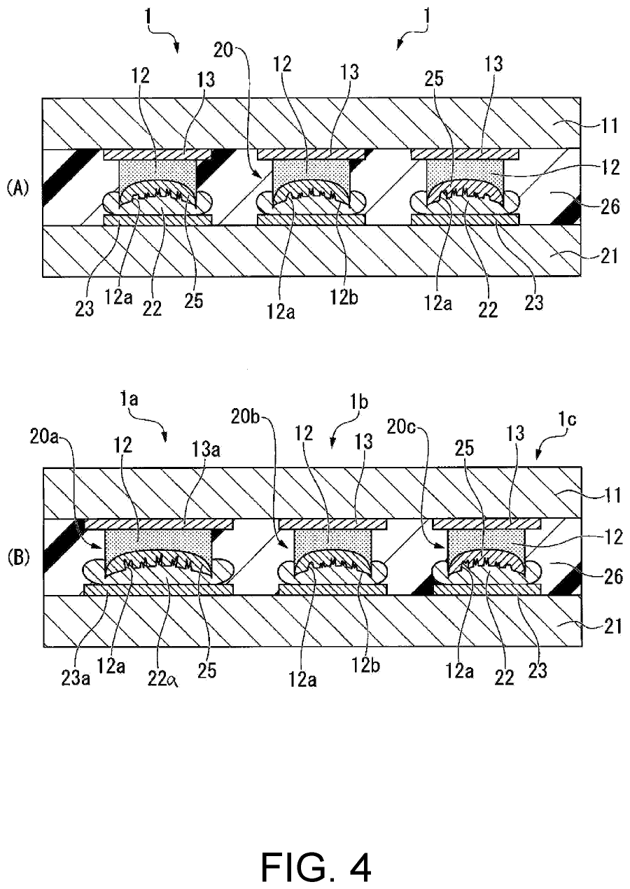

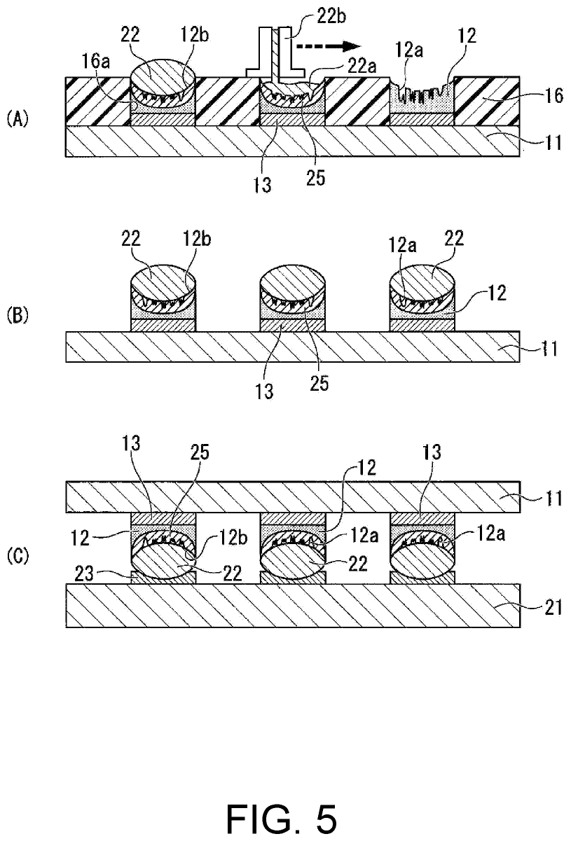

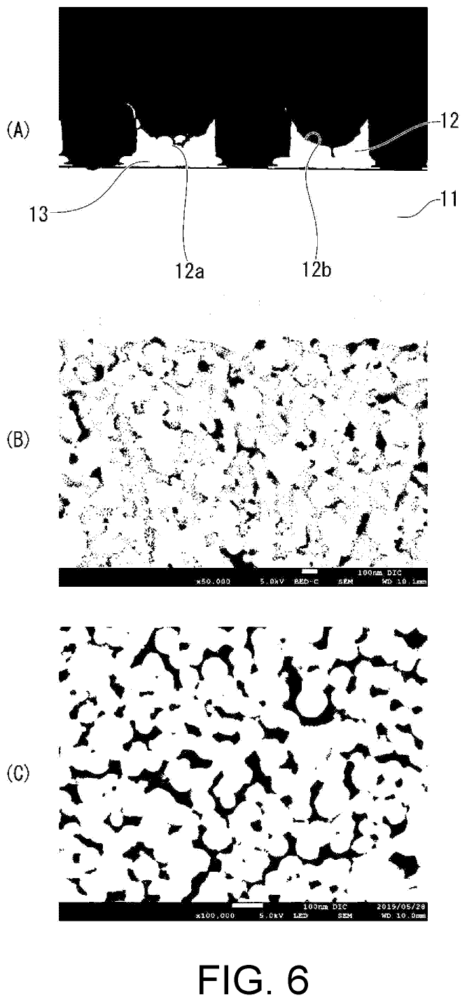

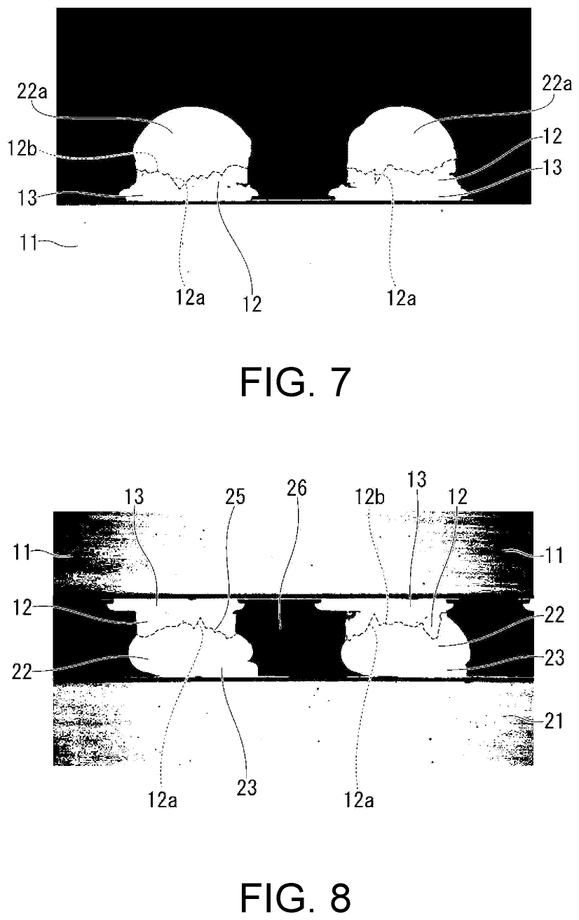

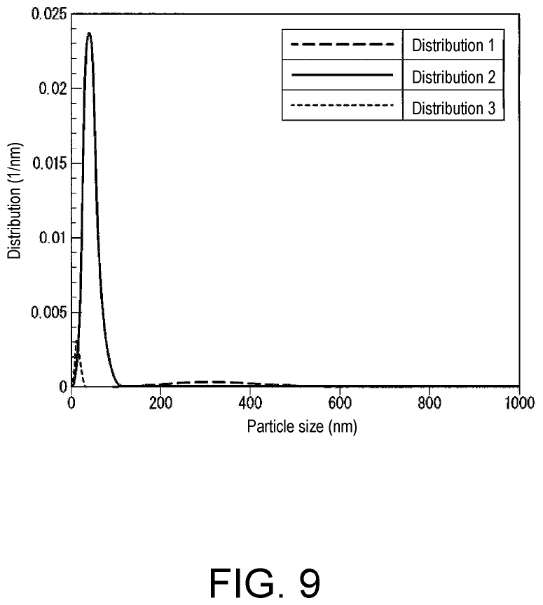

(A) of FIG. 2 is a plan view of the electrically conductive pillar shown in FIG. 1. (B) of FIG. 2 is a sectional view of the electrically conductive pillar taken along the line A-A′ shown in (A) of FIG. 2.

(A) of FIG. 3 to (C) of FIG. 3 are process views for illustrating an example of a method for manufacturing the electrically conductive pillar shown in FIGS. 1 and 2.

(A) of FIG. 4 is a sectional view of an example of a bonding structure of this embodiment. (B) of FIG. 4 is a sectional view of another example of the bonding structure of this embodiment.

(A) of FIG. 5 to (C) of FIG. 5 are process views for illustrating an example of a method for manufacturing bonding structures shown in (A) of FIG. 4.

(A) of FIG. 6 is a micrograph obtained by photographing cross sections of electrically conductive pillars of an example. (B) of FIG. 6 is an enlarged micrograph obtained by photographing portions of the cross sections of the electrically conductive pillars of the example shown in (A) of FIG. 6. (C) of FIG. 6 is a micrograph obtained by photographing upper surfaces of the electrically conductive pillars of the example.

FIG. 7 is a micrograph obtained by photographing a cross section in a state after bonding layers are formed along a concave shape of sintered bodies forming the electrically conductive pillars of the example and a resist layer is removed.

FIG. 8 is a micrograph obtained by photographing a cross section in a state in which a base member and a member to be bonded are bonded in an example and a sealing resin is packed therebetween.

FIG. 9 is a graph showing the particle size distribution of copper micro-particles.

### DESCRIPTION OF EMBODIMENTS

An electrically conductive pillar, a bonding structure, an electronic device, and a method for manufacturing an electrically conductive pillar of the present invention are described below in detail using the drawings. For a better understanding of features of the present invention, the drawings used in description below show characteristic portions on an enlarged scale for convenience in some cases. Therefore, the dimensional ratio and the like of components are different from those of actual components in some cases.

[Electrically Conductive Pillar]

FIG. 1 is a side view of an example of an electrically conductive pillar of this embodiment. (A) of FIG. 2 is a plan view of the electrically conductive pillar shown in FIG. 1. (B) of FIG. 2 is a sectional view of the electrically conductive pillar taken along the line A-A′ shown in (A) of FIG. 2.

As shown in FIG. 1, the electrically conductive pillar 1 of this embodiment is composed of a sintered body 12. As shown in FIG. 1, the sintered body 12 is disposed on a base member 11 having an electrode pad 13.

The base member 11 having the electrode pad 13 is not particularly limited. Examples of the base member 11 having the electrode pad 13 include semiconductor chips provided with any electric circuits, interposers, and the like. For example, known materials, including metals such as copper, ceramics, silicon, resins, and composite materials thereof, for use in the base member 11 can be used as material for the base member 11. An electrically conductive material made of metal such as Ti, Cu, Al, or Au or an alloy can be used as material for the electrode pad 13. The electrode pad 13 may be one having a single-layer structure made of one type of material or one having a multilayer structure made of two or more types of materials.

As shown in FIG. 1, (A) of FIG. 2, and (B) of FIG. 2, the sintered body 12 has a substantially columnar outer shape. When the sintered body 12 has such a substantially columnar outer shape, bonding to a bonding layer below is good and the base member 11 and a member to be bonded to the base member 11 are bonded together with higher bonding strength. This is preferable.

The size of the sintered body 12 (the size of the electrically conductive pillar 1) is preferably 100 μm or less in diameter, more preferably 50 μm or less, and particularly preferably 30 μm or less such that the sintered body 12 can meet the miniaturization of bonding structures in association with the downsizing of electronic devices. The size of the sintered body 12 (the size of the electrically conductive pillar 1) is preferably 5 μm or more in diameter and more preferably 20 μm or more because bonding to the bonding layer below and electrical conductivity are better.

The planar shape of the sintered body 12 is not limited to any substantially circular shape shown in (A) of FIG. 2 and may be determined depending on the planar shape of the electrode pad 13 or the like. The planar shape of the sintered body 12 may be, for example, a polygonal shape such as a substantially rectangular shape or a shape such as a substantially elliptical shape or a substantially oval shape.

An upper surface 12b of the sintered body 12 has a concave shape recessed on the base member 11 side as shown in (B) of FIG. 2. The concave shape is preferably a substantially hemispherical shape as shown in FIG. 1, (A) of FIG. 2, and (B) of FIG. 2. In this case, the contact area between the upper surface 12b of the sintered body 12 and the bonding layer below is large and the bonding between the sintered body 12 and the bonding layer is better. As a result, the base member 11 and the member to be bonded to the base member 11 are bonded together with higher bonding strength. This is preferable.

As shown in (B) of FIG. 2, the upper surface 12b of the sintered body 12 is preferably provided with a plurality of groove sections 12a that extend from the upper surface 12b toward the base member 11. When the sintered body 12 has the groove sections 12a, material to be formed into the bonding layer below is melted, enters the groove sections 12a, and is then solidified, whereby anchoring sections are formed. As a result, the bonding between the sintered body 12 and the bonding layer is better and the base member 11 and the member to be bonded to the base member 11 are bonded together with higher bonding strength. This is preferable.

The sintered body 12 is a sintered body of metal micro-particles with an average particle size of less than 1 μm and has a porous structure made of the metal micro-particles fused by sintering.

In this embodiment, a measurement value measured using a small-angle X-ray scattering (SAXS) method is used as the average particle size of the metal micro-particles forming the sintered body 12.

In this embodiment, the electrically conductive pillar 1 is the sintered body 12 of metal micro-particles with an average particle size of less than 1 μm and is therefore one that contains metal micro-particles at high density and that has good electrical conductivity. Since the electrically conductive pillar 1 is the sintered body 12 of the metal micro-particles with an average particle size of less than 1 μm, the electrically conductive pillar 1 contains a sufficient number of the metal micro-particles and therefore has sufficient electrical conductivity even if, for example, the sintered body 12 is substantially columnar and has a small diameter of 100 μm or less such that the sintered body 12 can meet the miniaturization of bonding structures. Thus, the electrically conductive pillar 1 of this embodiment can meet the miniaturization of bonding structures.

Since the electrically conductive pillar 1 is the sintered body 12 of the metal micro-particles with an average particle size of less than 1 μm, the surface area of the metal micro-particles exposed on a surface of the sintered body 12 is larger as compared to that of sintered bodies of metal micro-particles with an average particle size of 1 μm or more. Therefore, the bonding and electrical connection between the sintered body 12, the electrode pad 13, and the bonding layer are good.

Furthermore, since the electrically conductive pillar 1 is the sintered body 12 of the metal micro-particles with an average particle size of less than 1 μm, the shape of the electrically conductive pillar 1 can be formed by a fusion function of metal micro-particles obtained by sintering.

In contrast, when the average particle size of metal micro-particles is 1 μm or more, the shape of an electrically conductive pillar is not formed using a fusion function of the metal micro-particles by sintering. Thus, when the average particle size of metal micro-particles is 1 μm or more, a binder resin for bonding the metal micro-particles needs to be contained in an electrically conductive pillar. Accordingly, when the average particle size of metal micro-particles is 1 μm or more, heat resistance performance is poorer as compared to that of the electrically conductive pillar 1 of this embodiment. The electrically conductive pillar 1 is more preferably the sintered body 12 of metal micro-particles with an average particle size of 100 nm or less as measured using SAXS. When the average particle size of metal micro-particles is 100 nm or less, the electrically conductive pillar 1 contains the metal micro-particles at higher density and is composed of the sintered body 12 in which the surface area of the metal micro-particles exposed on a surface is larger. This is preferable.

A metal species used as metal micro-particles is preferably one or more selected from Au, Ag, Cu, and Ni and more preferably one or more metals selected from Ag and Cu from a viewpoint of the stability of the metal micro-particles. The metal species may be a single species, a mixture of two or more species, or an alloy containing two or more types of metal elements.

[Method for Manufacturing Electrically Conductive Pillar]

Next, a method for manufacturing an electrically conductive pillar of this embodiment is described in detail with reference to an example. (A) of FIG. 3 to (C) of FIG. 3 are process views for illustrating an example of a method for manufacturing the electrically conductive pillar 1 shown in FIGS. 1 and 2.

In this embodiment, an example in which three electrically conductive pillars 1 are formed on a base member 11 as shown in (A) of FIG. 3 to (C) of FIG. 3 is described. The number of electrically conductive pillars 1 formed on the substrate 11 is not limited to three, may be one, two, or four or more, and is determined as required. The arrangement of a plurality of the electrically conductive pillars 1 formed on the substrate 11 is appropriately determined depending on the arrangement of electrode pads 13 provided on the base member 11.

In order to manufacture the electrically conductive pillar 1 shown in FIG. 1, a resist layer 16 is formed on the base member 11 having the electrode pad 13. For example, various dry films such as photo-resist, polyimide, epoxy, and epoxy-molding compound (EMC) can be used as material for the resist layer 16.

Next, in this embodiment, the resist layer 16 is partly removed by patterning the resist layer 16, whereby resist opening sections 16a composed of columnar concave sections for exposing the electrode pads 13 are formed (refer to (A) of FIG. 3). A known method can be used as a method for patterning the resist layer 16. The resist opening sections 16a function as templates for manufacturing sintered bodies 12.

Subsequently, columnar bodies are formed on the base member 11 using metal micro-particles with an average primary particle size of less than 1 μm. Specifically, as shown in (B) of FIG. 3, the resist opening sections 16a are filled with an electrically conductive paste 12c containing the metal micro-particles using a squeegee 12d.

The filling of the resist opening sections 16a with the electrically conductive paste 12c may be performed in an inert atmosphere, such as an argon gas atmosphere, or a reducing gas atmosphere. In this case, the metal micro-particles contained in the electrically conductive paste 12c are unlikely to be oxidized. This is preferable.

One made of, for example, plastic, rubber such as urethane rubber, ceramic, metal, or the like can be used as the squeegee 12d, which is used to pack the electrically conductive paste 12c.

A method for filling the resist opening sections 16a with the electrically conductive paste 12c is not limited to a method in which the squeegee 12d is used. A method such as a doctor blade, a dispenser, ink jet, press injection, vacuum printing, or squeezing by pressing may be used.

In this embodiment, one containing the metal micro-particles with an average primary particle size of less than 1 μm is used as the electrically conductive paste 12c which is packed into the resist opening sections 16a. For example, a mixture of the metal micro-particles with an average primary particle size of less than 1 μm, a solvent, and a dispersant, a protective agent, and another additive, which are contained as required, or the like can be used as the electrically conductive paste 12c. The metal micro-particles and the dispersant may be contained in the electrically conductive paste 12c in the form of a composite of the metal micro-particles and the dispersant. The metal micro-particles and the protective agent may be contained in the electrically conductive paste 12c in the form of a composite of the metal micro-particles and the protective agent. The electrically conductive paste 12c can be produced in such a manner that, for example, materials to be formed into the electrically conductive paste 12c are mixed by a known method.

A metal species of the metal micro-particles contained in the electrically conductive paste 12c, which is used as material for the electrically conductive pillars 1 uses one that corresponds to metal micro-particles that form the electrically conductive pillars 1 that are manufactured is used. The shape of the metal micro-particles contained in the electrically conductive paste 12c is not particularly limited. For example, spherical or flaky metal micro-particles can be used as the metal micro-particles.

In this embodiment, the average primary particle size of the metal micro-particles which are used as material for the electrically conductive pillars 1 is appropriately determined such that the average particle size of metal micro-particles which form the sintered bodies 12 (the electrically conductive pillars 1) after sintering is within a predetermined range as measured using SAXS. For example, when an electrically conductive pillar 1 composed of a sintered body 12 of metal micro-particles with an average particle size of less than 1 μm as measured using SAXS is manufactured, the average primary particle size of the metal micro-particles contained in the electrically conductive paste 12c is less than 1 μm. When an electrically conductive pillar 1 composed of a sintered body 12 of metal micro-particles with an average particle size of 100 nm or less as measured using SAXS is manufactured, the average primary particle size of the metal micro-particles contained in the electrically conductive paste 12c is 100 nm or less.

In this embodiment, a fact that the particle size of the metal micro-particles which are used as material for the electrically conductive pillars 1 is less than 1 μm means that the average primary particle size of metal micro-particles is less than 1 μm.

The average primary particle size of the metal micro-particles which are used as material for the electrically conductive pillars 1 can be calculated by transmission electron microscope (TEM) observation.

In this embodiment, a value calculated by analyzing a photographic image photographed using a TEM is used as the average primary particle size of the metal micro-particles which are used as material for the electrically conductive pillars 1.

Specifically, a dispersion obtained by dispersing metal micro-particles in a solvent at an arbitrary concentration is cast on a carbon film-coated grid and the solvent is removed by drying, whereby a sample for TEM observation is prepared. Two hundred micro-particles are extracted from an obtained TEM image at random. The area of each of the extracted micro-particles is determined and a value obtained by calculating the size of particles converted into spheres on a number basis is used as an average primary particle size. Two overlapping particles are excluded from the metal micro-particles extracted at random. When a large number of particles are in contact with each other or secondarily aggregate to form clusters, metal micro-particles forming clusters are each treated as an independent particle. When, for example, five primary particles are in contact with each other or secondarily aggregate to form a cluster, each of the five particles forming the cluster is intended for the calculation of the average primary particle size of metal micro-particles.

One that does not aggregate the metal micro-particles (a composite when the metal micro-particles and the dispersant form the composite and/or the metal micro-particles and a protective agent form the composite) contained in the electrically conductive paste 12c is preferably used as the solvent contained in the electrically conductive paste 12c such that the electrically conductive paste 12c in which the metal micro-particles are uniformly dispersed is obtained. As the solvent, one or more solvents containing a hydroxy group, one or more solvents containing no hydroxy group, or a mixture of a solvent containing a hydroxy group and a solvent containing no hydroxy group may be used.

Examples of the solvent containing the hydroxy group include water, methanol, ethanol, 1-propanol, isopropanol, 1-butanol, isobutanol, sec-butanol, tert-butanol, amyl alcohol, tert-amyl alcohol, 1-hexanol, cyclohexanol, benzyl alcohol, 2-ethyl-1-butanol, 1-heptanol, 1-octanol, 4-methyl-2-pentanol, neopentyl glycol, ethylene glycol, propylene glycol, 1,3-butanediol, 1,4-butanediol, 2,3-butanediol, isobutylene glycol, 2,2-dimethyl-1,3-butanediol, 2-methyl-1,3-pentanediol, 2-methyl-2,4-pentanediol, diethylene glycol, triethylene glycol, tetraethylene glycol, 1,5-pentanediol, 2,4-pentanediol, dipropylene glycol, 2,5-hexanediol, glycerin, diethylene glycol monobutyl ether, ethylene glycol monobenzyl ether, ethylene glycol monoethyl ether, ethylene glycol monomethyl ether, ethylene glycol monophenyl ether, propylene glycol dimethyl ether, and the like.

Examples of the solvent containing no hydroxy group include acetone, cyclopentanone, cyclohexanone, acetophenone, acrylonitrile, propionitrile, n-butyronitrile, isobutyronitrile, γ-butyrolactone, ε-caprolactone, propiolactone, 2,3-butylene carbonate, ethylene carbonate, 1,2-ethylene carbonate, dimethyl carbonate, ethylene carbonate, dimethyl malonate, ethyl lactate, methyl benzoate, methyl salicylate, ethylene glycol diacetate, ε-caprolactam, dimethyl sulfoxide, N,N-dimethylformamide, N,N-dimethylacetamide, N-methylformamide, N-methylacetamide, N-ethylacetamide, N,N-diethyformamide, formamide, pyrrolidine, 1-methyl-2-pyrrolidinone, hexamethylphosphoric triamide, naphthalene, and the like.

Examples of an additive contained in the electrically conductive paste 12c include silicon-based leveling agents, fluorinated leveling agents, antifoaming agents, and the like.

For example, thioether-type organic compounds and the like can be used as a dispersant contained in the electrically conductive paste 12c. Examples of a thioether-type organic compound suitable as a dispersant include ethyl 3-(3-(methoxy (polyethoxy) ethoxy)-2-hydroxypropylsulfanyl) propionate [an addition compound of ethyl 3-mercaptopropionate with polyethylene glycol methylglycidyl ether (a polyethylene glycol chain with a molecular weight of 200 to 3,000 (eight to 136 carbon atoms))] represented by Formula (1) below and the like.

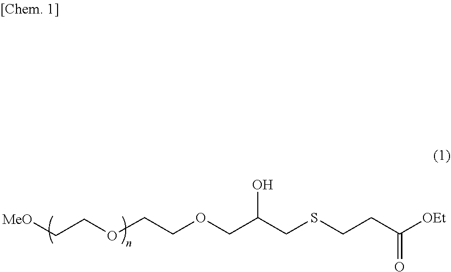

(In Formula (1), Me represents a methyl group, Et represents an ethyl group, and n is 200 to 3,000.)

The compound represented by Formula (1) is an addition compound of ethyl 3-mercaptopropionate with polyethylene glycol methylglycidyl ether and is one in which the molecular weight of a polyethylene glycol chain in polyethylene glycol methylglycidyl ether is 200 to 3,000 (eight to 136 carbon atoms). Specifically, examples of the compound represented by Formula (1) include those having a polyethylene glycol chain with a molecular weight of 200 (eight carbon atoms), 1,000 (46 carbon atoms), 2,000 (91 carbon atoms), or 3,000 (136 carbon atoms) and the like.

When the molecular weight of a polyethylene glycol chain in polyethylene glycol methylglycidyl ether is 200 or more, the metal micro-particles can be dispersed in the solvent well and aggregation due to a dispersion failure can be suppressed. When the molecular weight is 3,000 or less, the dispersant is unlikely to remain in the sintered bodies 12 which are formed by sintering the electrically conductive paste 12c. As a result, the wettability of the sintered bodies 12 with the material to be formed into the bonding layer below is good, the groove sections 12a of the sintered body 12 are likely to be filled with the material to be formed into the bonding layer, and the anchoring sections are likely to be formed.

The compound represented by Formula (1) forms a composite with metal micro-particles. A composite of the compound represented by Formula (1) and the metal micro-particles is readily uniformly dispersed in a solvent such as water or ethylene glycol. Thus, using the composite of the compound represented by Formula (1) and the metal micro-particles allows the electrically conductive paste 12c in which the metal micro-particles are uniformly dispersed to be readily obtained. Using the electrically conductive paste 12c in which the metal micro-particles are uniformly dispersed allows the electrically conductive pillars 1 in which the metal micro-particles are uniformly arranged and which have stable characteristics to be obtained.

A composite of the metal micro-particles and the dispersant can be produced by, for example, a method in which the metal micro-particles and the dispersant are mixed together and are allowed to react. Examples of the composite of the metal micro-particles and the dispersant include Composites [1] and [2] produced by a method below and the like. After being purified as required, Composites [1] and [2] may be used as materials for the electrically conductive paste 12c.

<Production of Composite [1]>

A mixture of copper (II) acetate monohydrate, the compound represented by Formula (1) as a dispersant, and ethylene glycol is heated with nitrogen injected into the mixture. The mixture is stirred, is deaerated, and is then returned to room temperature. Next, a hydrazine solution prepared by diluting hydrazine hydrate with water is added dropwise to the mixture returned to room temperature, whereby copper is reduced.

Through the above steps, Composite [1] of metal micro-particles made of copper and a dispersant made of the compound represented by Formula (1) is obtained.

<Production of Composite [2]>

A mixed solution of dimethylaminoethanol as a reducing agent and distilled water is added dropwise to a mixture of silver (I) nitrate, the compound represented by Formula (1) as a dispersant, and distilled water. Thereafter, the mixed solution is heated and a reduction reaction is terminated.

Through the above steps, Composite [2] of metal micro-particles made of silver and a dispersant made of the compound represented by Formula (1) is obtained.

For example, amine compounds, carboxylic acids, carboxylates, and the like can be used as a protective agent contained in the electrically conductive paste 12c. One or more selected from, for example, octylamine, N,N-dimethylethylenediamine, and 3-(2-ethylhexyloxy)propylamine are cited as an amine compound suitable as the protective agent. Linoleic acid and the like are cited as a carboxylic acid suitable as the protective agent.

Octylamine, N,N-dimethylethylenediamine, 3-(2-ethylhexyloxy)propylamine, and linoleic acid each form a composite with metal micro-particles, suppress the reaction of metal with oxygen, and prevent the oxidation of the metal micro-particles. Thus, using the electrically conductive paste 12c containing these composites allows the electrically conductive pillars 1 in which the oxidation of the metal micro-particles is suppressed and which have good electrical conductivity to be obtained.

A composite of the metal micro-particles and the protective agent can be produced by, for example, a method in which the metal micro-particles and the protective agent are mixed together and are allowed to react. Examples of the composite of the metal micro-particles and the protective agent include Composites [3] and [4] produced by a method below and the like. After being purified as required, Composites [3] and [4] may be used as materials for the electrically conductive paste 12c.

<Production of Composite [3]>

Copper nitrate, octylamine as a protective agent, and linoleic acid are dissolved in trimethylpentane by mixing and stirring, whereby a mixed solution is prepared. Thereafter, a propanol solution containing sodium borohydride is added dropwise to the mixed solution, whereby copper is reduced.

Through the above steps, Composite [3] of metal micro-particles which are black solids and which are made of copper and a protective agent made of an organic substance is obtained.

<Production of Composite [4]>

A mixed solution containing N,N-dimethylethylenediamine and 3-(2-ethylhexyloxy)propylamine as protective agents is heated and stirred in an argon gas atmosphere. Furthermore, silver oxalate is added to the mixed solution. The mixed solution is heated, is stirred, and is allowed to react.

Through the above steps, Composite [4] of metal micro-particles made of silver and a protective agent made of an organic substance is obtained.

In this embodiment, after the columnar bodies are formed by filling the resist opening sections 16a with the electrically conductive paste 12c containing the metal micro-particles, a step of exposing at least a surface (an upper surface in (B) of FIG. 3) of each columnar body to an oxygen-containing atmosphere with an oxygen concentration of 200 ppm or more is preferably performed before the sintered bodies 12 are formed by sintering the columnar bodies. This allows the metal micro-particles contained in the electrically conductive paste 12c forming a surface of each columnar body to be oxidized.

The oxygen concentration of the oxygen-containing atmosphere to which at least a surface of the columnar body is exposed is preferably 200 ppm or more and more preferably 1,000 ppm or more. When the oxygen concentration of the oxygen-containing atmosphere is 200 ppm or more, the oxidation of the metal micro-particles contained in the electrically conductive paste 12c forming a surface of the columnar body is promoted and therefore the time for which at least a surface of the columnar body is exposed to the oxygen-containing atmosphere is short. This is preferable.

The oxygen concentration of the oxygen-containing atmosphere to which at least a surface of the columnar body is exposed is preferably 30% or less, more preferably 25% or less, and further more preferably less than or equal to the oxygen concentration (20.1%) of air. When the oxygen concentration of the oxygen-containing atmosphere is 30% or less, the metal micro-particles contained in the electrically conductive paste 12c forming the columnar body can be prevented from being excessively oxidized.

The exposure time for which at least a surface of the columnar body is exposed to the oxygen-containing atmosphere with an oxygen concentration 200 ppm or more can be appropriately determined depending on exposure temperature, the type of the metal micro-particles contained in the electrically conductive paste 12c, or the like. The exposure time is not particularly limited. When a surface of the columnar body is exposed to the oxygen-containing atmosphere with an oxygen concentration 200 ppm or more in an environment with a temperature of 25° C., the exposure time is preferably in the range of one minute to 180 minutes and more preferably in the range of three minutes to 60 minutes. When the exposure time is one minute or more, the metal micro-particles contained in the electrically conductive paste 12c forming a surface of the columnar body are sufficiently oxidized. As a result, a sufficient number of the groove sections 12a are formed by sintering the columnar body so as to have a sufficient depth. This is preferable. When the exposure time is 180 minutes or less, the metal micro-particles contained in the electrically conductive paste 12c forming a surface of the columnar body can be prevented from being excessively oxidized.

If the metal micro-particles contained in the columnar bodies are excessively oxidized before the sintered bodies 12 are formed by sintering the columnar bodies, then the electrical conductivity of the sintered bodies 12 obtained after sintering may possibly be insufficient. When the metal micro-particles contained in the columnar bodies are excessively oxidized, the sintered bodies 12 may be reduced by a conventionally known method as required after the sintered bodies 12 are formed.

The oxygen-containing atmosphere with an oxygen concentration 200 ppm or more is, for example, air.

Next, the columnar bodies are sintered, whereby the sintered bodies 12 are formed so as to have an upper surface 12b having a concave shape recessed on the base member 11 side as shown in (C) of FIG. 3. The concave shape of the sintered bodies 12 is supposed to be formed because the columnar bodies (electrically conductive paste 12c) which have good wettability with the resist 16 are reduced in volume as compared to the columnar bodies by sintering the columnar bodies made of the electrically conductive paste 12c in such a manner that a state in which the columnar bodies are in close contact with inner surfaces of the resist opening sections 16a is maintained and the metal micro-particles contained in the columnar bodies are fused.

When the step of exposing at least a surface (an upper surface in (B) of FIG. 3) of each columnar body to the oxygen-containing atmosphere with an oxygen concentration of 200 ppm or more is performed before a step of forming the sintered bodies 12, the groove sections 12a are formed in the upper surfaces 12b of the sintered bodies 12 by sintering the columnar bodies so as to extend from the upper surfaces 12b toward the base member 11 as shown in (C) of FIG. 3. This is probably because the metal micro-particles contained in the electrically conductive paste 12c forming a surface of each of the columnar bodies that are converted into the sintered bodies 12 have been oxidized.

In conventional techniques, when a wiring line made from a sintered body is formed in such a manner that paste containing metal micro-particles such as copper micro-particles is applied to a base member and is sintered, a series of steps from a step of applying the paste containing the metal micro-particles to the base member to the completion of sintering are performed in an inert gas atmosphere. This is for the purpose of preventing metal micro-particles, such as copper micro-particles, contained in a metal micro-particle-containing paste from being oxidized (refer to, for example, Japanese Patent No. 6,168,837 and Japanese Patent No. 6,316,683). Thus, in conventional techniques, no atmosphere is changed halfway through a series of steps from a step of applying paste containing metal micro-particles to a base member to the completion of sintering, the paste, containing metal micro-particles, applied to the base member is not exposed to any atmosphere containing oxygen before being sintered, or no groove sections have not been formed in an upper surface of a sintered body.

In this embodiment, before the columnar bodies are fired, the columnar bodies may be pre-fired as required such that the solvent contained in the columnar bodies is vaporized at low temperature.

A firing method for firing the columnar bodies is not particularly limited and, for example, a vacuum solder reflow system, a hotplate, a hot-air oven, and the like can be used.

The sintering temperature and sintering time of the columnar bodies may be in a range in which the metal micro-particles contained in the columnar bodies (electrically conductive paste 12c) fuse and the sintered bodies 12 having sufficient electrical conductivity and strength are obtained. The sintering temperature is preferably 150° C. to 350° C. and more preferably 200° C. to 250° C. The sintering time is preferably in the range of one minute to 60 minutes and more preferably in the range of five minutes to 15 minutes.

The temperature at which the metal micro-particles fuse varies depending on a metal species used in the metal micro-particles. The temperature at which the metal micro-particles fuse can be measured using a thermogravimetric analyzer (TG-DTA) or a differential scanning calorimeter (DSC).

An atmosphere for sintering is not particularly limited and may be determined depending on the metal species used in the metal micro-particles. For example, when the metal species in the metal micro-particles is a noble metal, an inert gas atmosphere or air may be used. When the metal species in the metal micro-particles is a base metal, sintering is preferably performed in an inert gas atmosphere such as a nitrogen gas or an argon gas. When the metal species in the metal micro-particles is a base metal, a forming gas containing hydrogen or gas containing a reducing component such as formic acid may be used as an atmosphere for sintering.

Through the above steps, the electrically conductive pillars 1 of this embodiment are obtained.

In a method for manufacturing the electrically conductive pillars 1 of this embodiment, in order to manufacture the sintered bodies 12 of the metal micro-particles with an average particle size of less than 1 μm as measured using SAXS, the electrically conductive paste 12c containing the metal micro-particles with an average primary particle size of less than 1 μm is used. The electrically conductive paste 12c, in which the average primary particle size of the metal micro-particles is less than 1 μm, is good in filling properties when the resist opening sections 16a are filled. Thus, the electrically conductive pillars 1, which are composed of the sintered bodies 12 formed by sintering the electrically conductive paste 12c (the columnar bodies) packed in the resist opening sections 16a, contain the metal micro-particles at high density and have good electrical conductivity. Since the electrically conductive paste 12c has good filling properties, a fine electrically conductive pillar 1 that can meet the miniaturization of bonding structures can be formed. In addition, since the electrically conductive paste 12c has good filling properties, the sintered bodies 12 formed by sintering the electrically conductive paste 12c (the columnar bodies) are good in bonding and electrical connection to the electrode pads 13 and the bonding layer below.

When the electrically conductive pillars 1 of this embodiment are sintered bodies 12 of metal micro-particles with an average particle size of 100 nm or less as measured using SAXS, one containing the metal micro-particles with an average primary particle size of 100 nm or less is used as an electrically conductive paste 12c. This electrically conductive paste 12c is better in filling properties when the resist opening sections 16a are filled. This is more preferable. Specifically, when the average primary particle size of metal micro-particles contained in this electrically conductive paste 12c is 100 nm or less, this electrically conductive paste 12c can be densely packed into the resist opening sections 16 even if, for example, the resist opening sections 16a are fine ones having a columnar shape with a diameter of 100 μm.

In contrast, for example, when an electrically conductive paste containing metal micro-particles with an average primary particle size of 1 μm or more is used to manufacture a sintered body of metal micro-particles with an average primary particle size of 1 μm or more as measured using SAXS, the packing of the electrically conductive paste into a resist opening section is insufficient. Thus, it is difficult to manufacture a fine electrically conductive pillar. This is unlikely to meet the miniaturization of bonding structures.

In the method for manufacturing the electrically conductive pillars 1 of this embodiment, since the average primary particle size of the metal micro-particles contained in the electrically conductive paste 12c is less than 1 μm, the shape of the electrically conductive pillars 1 can be formed by a fusion function of metal micro-particles obtained by sintering the paste 12c (the columnar bodies).

[Bonding Structure]

Next, a bonding structure of this embodiment is described in detail. (A) of FIG. 4 is a sectional view of an example of the bonding structure of this embodiment. A bonding structure 20 shown in (A) of FIG. 4 includes the electrically conductive pillar 1 of the above-mentioned embodiment.

As shown in (A) of FIG. 4, the bonding structure 20 of this embodiment is disposed between a base member 11 and a member 21 to be bonded, the member 21 to be bonded being disposed opposite to the base member 11. The member 21 to be bonded is, for example, a semiconductor package which is provided with any electric circuit and which has an electrode 23 on a surface thereof or the like.

(A) of FIG. 4 shows three bonding structures 20 disposed between the base member 11 and the member 21 to be bonded. The number of the bonding structures 20 disposed between the base member 11 and the member 21 to be bonded is not limited to three; may be one, two, or four; and is determined as required.

The bonding structure 20 of this embodiment includes the electrically conductive pillar 1 of this embodiment and a bonding layer 22 provided along the concave shape of the electrically conductive pillar 1. In the bonding structures 20 shown in (A) of FIG. 4, the electrically conductive pillars 1 shown in (C) of FIG. 3 are arranged in such a state that a vertical direction in (C) of FIG. 3 is reversed.

In this embodiment, an example in which the bonding layer 22 has a single-layer structure made of one type of material is described. The bonding layer may be one having a multilayer structure in which two or more types materials are layered.

As material for the bonding layer 22, Au, Ag, Cu, Sn, Ni, solder alloys, and the like can be used and an alloy containing one or more metals selected from Sn, Pb, Ag, and Cu is preferably used. The bonding layer 22 may be made of a single component only or may contain a plurality of components.

As a solder alloy used as material for the bonding layer 22, a Sn—Ag alloy; a Sn—Pb alloy; a Sn—Bi alloy; a Sn—Zn alloy; a Sn—Sb alloy; a Sn—Bi alloy; a Sn—In alloy; a Sn—Cu alloy; an alloy made by adding two or more elements selected from the group consisting of Au, Ag, Bi, In, and Cu to Sn; and the like can be used.

As shown in (A) of FIG. 4, the bonding structure 20 is provided with anchoring sections formed by a plurality of groove sections 12a that extend from the upper surface 12b (in (A) of FIG. 4, a lower surface) of the electrically conductive pillar 1 toward the base member 11 being filled with portions of the bonding layer 22. Therefore, in the bonding structure 20 of this embodiment, the sintered body 12 of the electrically conductive pillar 1 and the bonding layer 22 are bonded together with higher bonding strength.

As shown in (A) of FIG. 4, the bonding structure 20 of this embodiment includes an intermetallic compound layer 25 at the interface between the electrically conductive pillar 1 and the bonding layer 22. The intermetallic compound layer 25 enhances the bonding strength between the electrically conductive pillar 1 and the bonding layer 22. The intermetallic compound layer 25 is formed in such a manner that a component in the bonding layer 22 diffuses toward an inner portion of the electrically conductive pillar 1 and a metal micro-particle component in the electrically conductive pillar 1 (the sintered body 12) diffuses toward an inner portion of the bonding layer 22. Thus, the composition of the intermetallic compound layer 25 varies depending on metal species forming the electrically conductive pillar 1 (sintered body 12) and bonding layer 22 and sintering conditions.

As shown in (A) of FIG. 4, a sealing resin 26 is packed in a region which is located between the base member 11 and the member 21 to be bonded and in which no bonding structure 20 is disposed. A conventionally known one such as an epoxy resin can be used as material for the sealing resin 26.

[Method for Manufacturing Bonding Structure]

Next, a method for manufacturing the bonding structure 20 of this embodiment that is shown in (A) of FIG. 4 is described in detail using an example in which bonding structures are manufactured using the electrically conductive pillars 1 shown in (C) of FIG. 3.

(A) of FIG. 5 to (C) of FIG. 5 are process views for illustrating an example of the method for manufacturing bonding structures shown in (A) of FIG. 4.

In order to manufacture the bonding structures 20 shown in (A) of FIG. 4, as shown in (A) of FIG. 5, material 22a to be formed into the bonding layers 22 is supplied to a concave shape of the sintered bodies 12 that is recessed on the base member 11 side shown in (C) of FIG. 3, is melted (reflowed), and is solidified. This allows bumps composed of the bonding layers 22 to be provided along the concave shape of the sintered bodies 12. As shown in (A) of FIG. 5, the obtained bonding layers 22 have a raised shape like a convex curved surface due to the difference in surface energy between a resist layer 16 and the material 22a to be formed into the bonding layers 22.

For example, printing methods such as a stencil mask method and a dry film method, a ball mount method, a vapor deposition method, an injection molded solder method (IMS method), and the like can be used as a method for supplying the material 22a to be formed into the bonding layers 22 to the concave shape of the sintered bodies 12. Among these, in particular, an IMS method in which molten solder is embedded in the concave shape of the sintered bodies 12 using an injection head 22b as shown in (A) of FIG. 5 is preferably used. Using the IMS method enables solder that is the material 22a to be formed into the bonding layers 22 to be supplied to the concave shape of the sintered bodies 12 in a molten state. This is preferable.

In this embodiment, as shown in (A) of FIG. 5, the upper surface 12b of each sintered body 12 is provided with a plurality of groove sections 12a that extend from the upper surface 12b toward the base member 11. Thus, melting (reflowing) the material 22a to be formed into the bonding layers 22 allows the material 22a to be formed into the bonding layers 22 to enter the groove sections 12a, so that the groove sections 12a are filled with the material 22a to be formed into the bonding layers 22, whereby anchoring sections are formed. Furthermore, the molten material 22a to be formed into the bonding layers 22 enters a porous structure of the sintered bodies 12 and solidifies.

The material 22a to be formed into the bonding layers 22 that is supplied to the concave shape of the sintered bodies 12 forms intermetallic compound layers 25 with the metal micro-particle component in the electrically conductive pillars 1 (the sintered bodies 12). The sintered bodies 12 are porous structures and therefore have a large specific surface area. Therefore, in this embodiment, the intermetallic compound layers 25 are quickly formed as compared to, for example, when an electrically conductive pillar is one which is formed using an electroplating method or the like and which is made of a dense bulk metal.

Next, as shown in (B) of FIG. 5, the resist layer 16 is removed. A known method can be used as a method for removing the resist layer 16.

In this embodiment, an example in which the resist layer 16 is removed after the bonding layers 22 are formed has been described. The resist layer 16 need not be removed after the bonding layers 22 are formed. When the resist layer 16 is not removed, the resist layer 16 is placed between the base member 11 and the member to be bonded in such a manner that the base member 11 and the member to be bonded as described below are stacked.

Next, the base member 11 and the member 21 to be bonded are electrically connected by a flip-chip packaging method. Specifically, as shown in (C) of FIG. 5, the base member 11 having the sintered bodies 12 and the bonding layers 22 formed thereon and the member 21 to be bonded are placed opposite to each other and are stacked. In this embodiment, the member 21 to be bonded is placed such that a surface of the member 21 to be bonded, the surface being provided with electrodes 23, faces upward and the base member 11 is placed such that a surface of the base member 11 that is provided with the bonding layers 22 faces downward. As shown in (C) of FIG. 5, a state in which the electrodes 23 of the member 21 to be bonded and the bonding layers 22 of the base member 11 are overlapped is created. Thereafter, the bonding layers 22 are melted by heating the base member 11 and the member 21 to be bonded in such a state that the base member 11 and the member 21 to be bonded are stacked, the base member 11 and the member 21 to be bonded are bonded together, and the bonding layers 22 are solidified.

Through the above steps, the bonding structures 20 shown in (A) of FIG. 4 are obtained.

Thereafter, as shown in (A) of FIG. 4, the sealing resin 26 is packed into a region which is located between the base member 11 and the member 21 to be bonded and in which no bonding structure 20 is disposed. A conventionally known method can be used as a method for packing the sealing resin 26.

The electrically conductive pillar 1 of this embodiment is composed of the sintered body 12 of the metal micro-particles that is disposed on the base member 11, the average particle size of the metal micro-particles is less than 1 μm as measured using SAXS, and the upper surface 12b (in (A) of FIG. 4, a lower surface) of the sintered body 12 has a concave shape recessed on the base member 11 side. Therefore, providing the bonding layer 22 along the concave shape of the electrically conductive pillar 1 allows the bonding layer 22 to be formed such that the bonding layer 22 enters the concave shape of the electrically conductive pillar 1. In addition, the electrically conductive pillar 1 of this embodiment is composed of the sintered body 12 of the metal micro-particles, which have an average particle size of less than 1 μm as measured using SAXS, and has a porous structure made of the metal micro-particles fused by sintering. Therefore, when the bonding layer 22 is formed, the molten material 22a to be formed into the bonding layer 22 enters the porous structure of the sintered body 12 and solidifies. These allow the electrically conductive pillar 1 of this embodiment to have a large bonding area with the bonding layer 22 and allow the electrically conductive pillar 1 of this embodiment to be bonded to the bonding layer 22 with higher bonding strength as compared to, for example, electrically conductive pillars which are formed by an electroplating method, which therefore have a flat upper surface parallel to a base member, and which are made of a dense metal. As a result, in accordance with the electrically conductive pillar 1 of this embodiment, the base member 11 and the member 21 to be bonded can be bonded together with high bonding strength with the bonding layer 22 interposed therebetween.

Since the electrically conductive pillar 1 of this embodiment is composed of the sintered body 12 of the metal micro-particles, which have an average particle size of less than 1 μm, and has the porous structure, which is made of the metal micro-particles fused by sintering, stress caused by a difference between thermal expansion coefficients can be reduced as compared to dense bulk metals formed using an electroplating method or the like and excellent durability is obtained.

A method for manufacturing the electrically conductive pillar 1 of this embodiment includes a step of forming a columnar body on the base member 11 using the metal micro-particles with an average particle size of less than 1 μm and a step of forming the sintered body 12, of which the upper surface 12b has the concave shape recessed on the base member 11 side, by sintering the columnar body. Thus, in accordance with the method for manufacturing the electrically conductive pillar 1 of this embodiment, the electrically conductive pillar 1 can be manufactured without using any electroplating method.

In contrast, in a case of forming a copper pillar on a base member using, for example, an electroplating method, when a plating base layer disposed under a resist layer is etched off after the copper pillar is formed, a portion of the base member is possibly removed together with plating base layer. Furthermore, in the case of forming the copper pillar using the electroplating method, a cost of introducing a facility necessary to form the copper pillar is high and environmental loads due to hazardous liquid wastes are large.

The bonding structure 20 of this embodiment is disposed between the base member 11 and the member 21 to be bonded and includes the electrically conductive pillar 1 of this embodiment and the bonding layer 22 provided along the concave shape of the electrically conductive pillar 1. Thus, the bonding structure 20 of this embodiment is such that the bonding layer 22 enters the concave shape of the electrically conductive pillar 1 and the base member 11 and the member 21 to be bonded are bonded together with high bonding strength with the bonding layer 22 interposed therebetween.

On the other hand, Patent Literature 1 discloses a method for preparing an electrically conductive pillar using metal particles. However, Patent Literature 1 does not at all describe the particle size of the metal particles. It has been unclear that what size of metal particles are used to prepare the electrically conductive pillar such that high bonding strength is obtained.

### Another Example

In this embodiment, an example in which the three bonding structures 20 disposed between the base member 11 and the member 21 to be bonded have substantially the same shape as shown in (A) of FIG. 4 has been described. When a plurality of bonding structures of this embodiment are disposed between the base member 11 and the member 21 to be bonded, one or part of the bonding structures may have different shapes. That is, the shape of an electrically conductive pillar and bonding layer that each bonding structure has can be appropriately determined depending on the planar shape of an electrode pad of the base member 11 and an electrode of the member 21 to be bonded.

(B) of FIG. 4 is a sectional view of another example of the bonding structure of this embodiment. The example shown in (B) of FIG. 4 is different from the example shown in (A) of FIG. 4 in the shape of the bonding structure only. Therefore, in (B) of FIG. 4, the same members as those shown in (A) of FIG. 4 are given the same reference numerals and will not be described in detail.

As shown in (B) of FIG. 4, a plurality of (three in the example shown in (B) of FIG. 4) bonding structures 20a, 20b, and 20c are disposed between a base member 11 and a member 21 to be bonded. In the bonding structures 20a, 20b, and 20c shown in (B) of FIG. 4, the planar shape of the bonding structure 20a, which is one of the bonding structures 20a, 20b, and 20c, is larger than that of the other bonding structures 20b and 20c and the other bonding structures 20b and 20c have the same shape.

More specifically, as shown in (B) of FIG. 4, the planar shape of an electrode pad 13a and electrode 23a in contact with the bonding structure 20a, which is one of the three bonding structures 20a, 20b, and 20c, is larger than that of other electrode pads 13 and electrodes 23. Therefore, the outside diameter (diameter) of a substantially columnar electrically conductive pillar 1a that the bonding structure 20a has is larger as compared to that of other electrically conductive pillars 1b and 1c. The size of a bonding layer 22a that the bonding structure 20a has is larger as compared to that of other bonding layers 22 that the other bonding structures 20b and 20c have. As shown in (B) of FIG. 4, the distance between the base member 11 and the member 21 to be bonded is substantially constant and the three bonding structures 20a, 20b, and 20c have the same length in a thickness direction of the base member 11.

The three bonding structures 20a, 20b, and 20c shown in (B) of FIG. 4 can be manufactured together using the same method as that used to manufacture the above-mentioned three bonding structures 20 shown in (A) of FIG. 4 except that resist opening sections having a shape corresponding to the outer shape of each of the electrically conductive pillars 1a, 1b, and 1c are formed in a step of patterning a resist layer 16. Thus, a case where the three bonding structures 20a, 20b, and 20c shown in (B) of FIG. 4 are manufactured and a case where the three bonding structures 20 shown in (A) of FIG. 4 are manufactured are not different in the dimensional accuracy of an obtained bonding structure and the number of manufacturing steps.

On the other hand, for example, when a plurality of copper pillars are formed on a base member using an electroplating method, failures described below occur if the copper pillars include a copper pillar with a different shape. That is, it is difficult to control the plating rate, so that the dimensional accuracy of a copper pillar is insufficient in some cases. Not all the copper pillars are formed together and manufacturing steps are very complicated in some cases. Thus, when a plurality of copper pillars are formed on a base member using an electroplating method, it is difficult to provide a plurality of copper pillars including a copper pillar with a different shape.

In (B) of FIG. 4, the three bonding structures 20a, 20b, and 20c disposed between the base member 11 and the member 21 to be bonded are shown. The number of the three bonding structures 20a, 20b, and 20c disposed between the base member 11 and the member 21 to be bonded is not limited to three; may be, for example, two of the bonding structures 20a and 20b only or four or more; and is determined as required.

In (B) of FIG. 4, an example in which the planar shape of all the electrically conductive pillars 1a, 1b, and 1c (the sintered bodies 12) is a substantially circular shape (refer to (A) of FIG. 2) has been described. The planar shape of each electrically conductive pillar is not limited to any substantially circular shape and may be appropriately determined depending on the planar shape of an electrode pad 13.

In (B) of FIG. 4, an example in which the three bonding structures 20a, 20b, and 20c have the same length in the thickness direction of the base member 11 has been described. One or all of the three bonding structures 20a, 20b, and 20c may be different in length in the thickness direction of the base member 11.

[Electronic Device]

An electronic device of this embodiment includes the bonding structure 20 of this embodiment. The electronic device of this embodiment preferably includes a plurality of bonding structures 20. In this case, part or all of the bonding structures 20 may be different in shape.

Specifically, the electronic device of this embodiment is a device which includes a plurality of bonding structures 20 of this embodiment and which has a three-dimensional (3D) packaging structure or a device which includes a plurality of bonding structures 20 of this embodiment and which has a 2.5-dimensional (2.5D) packaging structure.

Since the electronic device of this embodiment includes the bonding structure 20 of this embodiment, a base member 11 and a member 21 to be bonded are bonded together with high bonding strength.

### Examples

The present invention is further described below in detail with reference to examples. The present invention is not limited to the examples below.

[Production of Electrically Conductive Paste Containing Metal Microparticles]

An electrically conductive paste used to manufacture an electrically conductive pillar was produced by a method below so as to contain a composite of metal micro-particles and a dispersant and a solvent.

<Production of Water Dispersion of Composite>

A mixture of copper (II) acetate monohydrate (3.00 g, 15.0 mmol) (produced by Tokyo Chemical Industry Co., Ltd.), ethyl 3-(3-(methoxy (polyethoxy) ethoxy)-2-hydroxypropylsulfanyl)propionate [an addition compound of ethyl 3-mercaptopropionate with polyethylene glycol methylglycidyl ether (a polyethylene glycol chain with a molecular weight of 2,000 (91 carbon atoms))] (0.451 g) represented by Formula (1), and ethylene glycol (10 mL) (produced by Kanto Chemical Co., Inc.) was heated with nitrogen injected into the mixture at a flow rate of 50 mL/min and was stirred at 125° C. for two hours with nitrogen fed to the mixture, whereby the mixture was deaerated. The mixture was returned to room temperature and a diluted solution prepared by diluting hydrazine hydrate (1.50 g, 30.0 mmol) (produced by Tokyo Chemical Industry Co., Ltd.) with 7 mL of water was added dropwise to the mixture using a syringe pump. About one-fourth of the amount of the diluted solution was added dropwise to the mixture over two hours and the addition was suspended. After the mixture was stirred for two hours and the suppression of foaming was confirmed, the remaining amount of the diluted solution was further added dropwise to the mixture over one hour. An obtained brown solution was heated to 60° C. and was further stirred for two hours and a reduction reaction was terminated.

An obtained reaction mixture was circulated in a hollow fiber-type ultrafiltration membrane module (HIT-1-FUS1582, 145 cm², a molecular-weight cutoff of 150,000) manufactured by DAICEN MEMBRANE-SYSTEMS Ltd. in such a manner that the same amount of a 0.1% aqueous solution of hydrazine hydrate as an exuding filtrate was added to the reaction mixture until the amount of the filtrate exuding from the ultrafiltration membrane module reached about 500 mL, whereby the reaction mixture was purified. The supply of the 0.1% aqueous solution of hydrazine hydrate was stopped and the reaction mixture was concentrated by an ultrafiltration method, whereby an aqueous dispersion of a composite of 2.85 g of a thioether-type organic compound and copper micro-particles was obtained. The content of nonvolatile matter in the aqueous dispersion was 16%.

<Preparation of Electrically Conductive Paste>

In a 50 mL three-necked flask, 5 mL of the above aqueous dispersion was sealed. Water was completely removed in such a manner that the flask was heated to 40° C. using a water bath and nitrogen was fed at a flow rate of 5 ml/min under reduced pressure, whereby 1.0 g a dry powder of a copper micro-particle composite was obtained. To the obtained dry powder of the copper micro-particle composite, 0.11 g of ethylene glycol bubbled with nitrogen for 30 minutes in a glove bag filled with an argon gas was added as a solvent. After the ethylene glycol was added to the dry powder of the copper micro-particle composite, the ethylene glycol and the dry powder of the copper micro-particle composite were mixed for ten minutes in a mortar, whereby an electrically conductive paste with a metal micro-particle content of 90% was obtained.

<Measurement of Weight Reduction Rate by Thermogravimetric Analysis (TG-DTA)>

Onto an aluminium pan for thermogravimetric analysis, 2 mg to 25 mg of the dry powder of the synthesized copper micro-particle composite was accurately weighed. The aluminium pan was put on an EXSTAR TG/DTA 6300 differential thermogravimetric analyzer (manufactured by SII NanoTechnology Kabushiki Kaisha). The aluminium pan was heated from room temperature to 600° C. at a rate of 10° C. per minute in an inert gas atmosphere, whereby the weight reduction rate was measured at 100° C. to 600° C. From the results, it was confirmed that 3% of an organic substance having a polyethylene oxide structure was present in the dry powder of the copper micro-particle composite.

<Measurement of Average Primary Particle Size>

The average primary particle size of the synthesized copper micro-particle composite was measured by TEM observation. First, the dry powder of the synthesized copper micro-particle composite was diluted 100-fold with water, whereby a dispersion was prepared. Next, the dispersion was cast on a carbon film-coated grid, was dried, and was observed with a transmission electron microscope (instrument: TEMJEM-1400 (manufactured by JEOL Ltd.), an acceleration voltage of 120 kV). Two hundred particles of the copper micro-particle composite were extracted from an obtained TEM image at random and were measured for area and the particle size in terms of a perfect sphere was calculated on a number basis, whereby the average primary particle size was obtained. As a result, the average primary particle size of the synthesized copper micro-particle composite was 42 nm.

<Measurement of Average Particle Size of Metal Microparticles Forming Electrically Conductive Pillar>

A sintered body of the electrically conductive paste obtained by the above method was prepared by simulating a method for manufacturing an electrically conductive pillar of an example below. Specifically, the electrically conductive paste obtained by the above method was uniformly applied to a silicon wafer in an argon gas atmosphere so as to give a thickness 1 mm.

Next, the silicon wafer coated with the electrically conductive paste was exposed to air for 20 minutes in an environment with a temperature of 25° C.

Next, pre-firing was performed such that the solvent in the electrically conductive paste applied to the silicon wafer was vaporized at low temperature. Pre-firing was performed in such a manner that the silicon wafer coated with the electrically conductive paste was heated at 120° C. for five minutes in a nitrogen gas atmosphere using a desktop vacuum solder reflow system (manufactured by UniTemp GmbH).

Next, the electrically conductive paste applied to the silicon wafer was sintered, whereby the sintered body was formed. The electrically conductive paste was sintered in such a manner that the pre-fired silicon wafer was heated at 250° C. for 10 minutes in a nitrogen gas atmosphere containing a formic acid vapor using the desktop vacuum solder reflow system (manufactured by UniTemp GmbH).

The obtained sintered body was scraped off from the silicon wafer and a powder of a copper micro-particle sintered body was collected. The average particle size of the collected copper micro-particle sintered body was measured by a small-angle X-ray scattering (SAXS) method. The result can be regarded as the average particle size of metal micro-particles forming an electrically conductive pillar of an example below.

An X-ray diffractometer (trade name: SmartLab) manufactured by Rigaku Corporation was used to measure the average particle size of the copper micro-particles in the sintered body. Measurement was performed in a step mode in such a manner that the diffraction angle 20 was varied in the range of 0° to 4°. The step angle was 0.005° and the measurement time was five seconds.

The average particle size of the copper micro-particles was estimated by calculating measurement data obtained by SAXS using analysis software (NANO-Solver Ver. 3). The results are shown in FIG. 9. FIG. 9 is a graph showing the particle size distribution of the copper micro-particles. As shown in FIG. 9, the particle size of the copper micro-particles in the sintered body was 322 nm at a volume fraction of 6% (Distribution 1), 45 nm at a volume fraction of 91% (Distribution 2), and 15 nm at a volume fraction of 4% (Distribution 3). From this result, the average particle size of the copper micro-particles in the sintered body was estimated to be 59.112 nm.

<Preparation of Electrically Conductive Pillars>

Electrode pads in which Ti (a thickness of 50 nm) and Cu (250 nm) were deposited by a sputtering method in that order were formed on a silicon wafer with a diameter of four inches, whereby a base member having the electrode pads was prepared. Next, a resist resin was applied to a surface of the base member having the electrode pads, the surface being on the electrode pad side, followed by patterning, whereby a 30 μm thick resist layer having a plurality of resist opening sections composed of columnar concave sections with a diameter of 30 μm was formed. The aspect ratio (depth to diameter) of the resist opening sections was 1:1.

Next, the electrically conductive paste obtained by the above method was packed into the columnar resist opening sections by a method below, whereby columnar bodies composed of metal micro-particles were formed on the base member. The packing of the electrically conductive paste was performed in an argon gas atmosphere. The packing of the electrically conductive paste was performed by a method in which the electrically conductive paste was put on the base member and was applied thereto by sweeping a squeegee attached to a semiautomatic screen printer (manufactured by Seria Corporation) on the substrate at an attack angle of 70° and a movement speed of 10 mm/s forward and backward once. The squeegee used was a rectangular squeegee made of urethane rubber with a hardness of 70°.

Next, the base member provided with the columnar bodies was exposed to air for 20 minutes in an environment with a temperature of 25° C., whereby at least a surface of each columnar body was exposed to an oxygen-containing atmosphere with an oxygen concentration of 200 ppm or more.

Next, pre-firing was performed such that the solvent contained in the columnar bodies was vaporized at low temperature. Pre-firing was performed in such a manner that the base member provided with the columnar bodies was heated at 120° C. for five minutes in a nitrogen gas atmosphere using a desktop vacuum solder reflow system (manufactured by UniTemp GmbH).

Next, the columnar bodies were sintered, whereby sintered bodies having an upper surface with a concave shape recessed on the base member side were formed. The columnar bodies were sintered in such a manner that the pre-fired base member was heated at 250° C. for 10 minutes in a nitrogen gas atmosphere containing a formic acid vapor using the desktop vacuum solder reflow system (manufactured by UniTemp GmbH).

Through the above steps, electrically conductive pillars of an example were obtained.

(A) of FIG. 6 is a micrograph obtained by photographing cross sections of the electrically conductive pillars of the example. (B) of FIG. 6 is an enlarged micrograph obtained by photographing portions of the cross sections of the electrically conductive pillars of the example shown in (A) of FIG. 6. (C) of FIG. 6 is a micrograph obtained by photographing upper surfaces of the electrically conductive pillars of the example.

In (A) of FIG. 6, reference numeral 11 represents the base member, reference numeral 12 represents the sintered bodies, reference numeral 12a represents groove sections, reference numeral 12b represents the upper surfaces, and reference numeral 13 represents the electrode pads. As shown in (A) of FIG. 6, the electrically conductive pillars (the sintered bodies 12) of the example were such that the upper surfaces 12b had a concave shape recessed on the base member 11 side. The upper surface 12b of each electrically conductive pillar of the example was provided with the groove sections 12a extending from the upper surface 12b toward the base member 11.

As shown in (B) of FIG. 6 and (C) of FIG. 6, the electrically conductive pillars of the example had a porous structure made of the metal micro-particles fused by sintering.

Next, molten solder was supplied to a concave shape of the sintered bodies forming the electrically conductive pillars, the concave shape being recessed on the base member side, using an IMS (injection molded soldering) technique (refer to, for example, Japanese Unexamined Patent Application Publication No. 2015-106617), whereby bumps were provided along the concave shape of the sintered bodies. Specifically, the molten solder was directly ejected from an injection head (reservoir) that held the molten solder and was supplied to the resist opening sections. A solder alloy used was SAC305. This allowed bonding layers (the bumps) made of the solder alloy to be prepared. The obtained bonding layers had a raised shape like a convex curved surface. Thereafter, the resist layer was removed.

FIG. 7 is a micrograph obtained by photographing a cross section in a state after the bonding layers are formed along the concave shape of the sintered bodies forming the electrically conductive pillars of the example and the resist layer is removed.

As shown in FIG. 7, it could be confirmed that material 22a to be formed into the bonding layers entered the groove sections 12a formed in the upper surfaces 12b of the electrically conductive pillars (the sintered bodies 12) of the example, the groove sections 12a were filled with the material 22a to be formed into the bonding layers, and anchoring sections were formed. Furthermore, it could be confirmed that intermetallic compound layers were disposed at the interfaces between the sintered bodies 12 and the bonding layers.

Next, the base member provided with the bonding layers formed on the sintered bodies and a semiconductor package (a member to be bonded) having electrodes, made of copper, disposed on a surface thereof were placed opposite to each other and were stacked. Specifically, the member to be bonded was placed such that a surface of the member to be bonded, the surface being provided with the electrodes, faced upward and the base member was placed such that a surface of the base member that was provided with the bonding layers faced downward, thereby creating a state in which the electrodes of the member to be bonded and the bonding layers of the base member were overlapped. The base member and the member to be bonded were heated in such a state that the base member and the member to be bonded were staked, the bonding layers were melted, and the base member and the member to be bonded were bonded together, whereby bonding structures were formed. Thereafter, a sealing resin was packed into a region which was located between the base member and the member to be bonded and in which no bonding structures were disposed by a method for injecting an underfill agent made of an epoxy resin.

FIG. 8 is a micrograph obtained by photographing a cross section in a state in which a base member and a member to be bonded are bonded in an example and a sealing resin is packed therebetween. In FIG. 8, reference numeral 11 represents the base member, reference numeral 12 represents sintered bodies, reference numeral 12a represents groove sections, reference numeral 12b represents upper surfaces, reference numeral 13 represents electrode pads, reference numeral 21 represents the member to be bonded, reference numeral 22 represents bonding layers, reference numeral 23 represents electrodes, reference numeral 25 represents intermetallic compound layers, and reference numeral 26 represents the sealing resin.

As shown in FIG. 8, bonding structures having the sintered bodies 12 of electrically conductive pillars and the bonding layers 22 provided along a concave shape of the sintered bodies 12 were disposed between the base member 11 and the member 21 to be bonded.

(Evaluation)

A bonding structure of an example was evaluated for “bonding strength”, “insulation resistance”, and “reliability” by methods below.

### “Bonding Strength”

Eight bonding structures (Nos. 1 to 8) of examples were prepared and a bonding test specimen was taken from each of the eight bonding structures. The bonding test specimen was measured for bonding strength in such a manner that shear force was applied to the bonding test specimen by a method specified in JIS Z-03918-5:2003 “Test methods for lead-free solders”. The results are shown in Table 1.

As shown in Table 1, it could be confirmed that all the bonding structures of the examples had a bonding strength in the range of 170 MPa to 230 MPa, showed little variation in bonding strength, and had high bonding strength.

TABLE 1

| | No. 1 | No. 2 | No. 3 | No. 4 | No. 5 | No. 6 | No. 7 | No. 8 |
|---|---|---|---|---|---|---|---|---|
| Bonding | 178 | 182 | 196 | 206 | 207 | 211 | 215 | 220 |
| strength | | | | | | | | |
| (MPa) | | | | | | | | |

“Insulation Resistance” “Reliability”

The bonding structures of the examples were measured for insulation resistance in such a manner that a voltage of 3.7 V was applied to the bonding structures for 96 hours at a temperature of 130° C. and a relative humidity of 85%. As a result, the bonding structures of the examples had an insulation resistance of 1 MΩ or more and a rate of change in resistance of less than 10%.

From this, it could be confirmed that the bonding structures of the examples exhibited a good resistance and had excellent reliability.

### REFERENCE SIGNS LIST

1 Electrically conductive pillar(s)
11 Base member
12 Sintered body (bodies)
12a Groove sections
12b Upper surface(s)
12c Electrically conductive paste
12d Squeegee
13 Electrode pad(s)
16 Resist layer
16a Resist opening sections
20 Bonding structure(s)
21 Member to be bonded
22 Bonding layer(s)
22b Injection head
23 Electrode(s)
25 Intermetallic compound layer(s)
26 Sealing resin

1. An electrically conductive pillar composed of a sintered body of metal micro-particles disposed on a base member,
wherein an average particle size of the metal micro-particles is less than 1 μm as measured using a small-angle X-ray scattering method, and
an upper surface of the sintered body has a concave shape recessed on a base member side.

2. The electrically conductive pillar according to claim 1, wherein the metal micro-particles are made of one or more metals selected from Ag and Cu.

3. A bonding structure disposed between a base member and a member to be bonded, the member to be bonded being disposed opposite to the base member, the bonding structure comprising:
an electrically conductive pillar composed of a sintered body of metal micro-particles disposed on the base member, an average particle size of the metal micro-particles being less than 1 μm as measured using a small-angle X-ray scattering method, an upper surface of the sintered body having a concave shape recessed on a base member side; and
a bonding layer provided along the concave shape of the electrically conductive pillar.

4. The bonding structure according to claim 3, wherein the electrically conductive pillar has a plurality of groove sections that extend from the upper surface toward the base member and has anchoring sections made by the groove sections being filled with portions of the bonding layer.

5. The bonding structure according to claim 3, wherein the bonding layer is made of an alloy containing one or more metals selected from Sn, Pb, Ag, and Cu.

6. The bonding structure according to claim 3, comprising an intermetallic compound layer between the electrically conductive pillar and the bonding layer.

7. An electronic device comprising the bonding structure according to claim 3.

8. The electronic device according to claim 7, wherein a plurality of the bonding structures are included, and part or all of the bonding structures have different shapes.

9. A method for manufacturing an electrically conductive pillar, comprising: a step of forming a columnar body on a base member using metal micro-particles with an average primary particle size of less than 1 μm; and a step of forming on an upper surface a sintered body having a concave shape recessed on a base member side by sintering the columnar body.

10. The method for manufacturing the electrically conductive pillar according to claim 9, wherein the metal micro-particles are made of one or more metals selected from Ag and Cu.

11. The method for manufacturing the electrically conductive pillar according to claim 9, comprising a step of exposing at least a surface of the columnar body to an oxygen-containing atmosphere with an oxygen concentration of 200 ppm or more before the step of forming the sintered body.
